(19) United States
(12) Patent Application Publication
(10) Pub. No.: US 2015/0368803 A1
(43) Pub. Date: Dec. 24, 2015

(54) UV CURING PROCESS TO IMPROVE MECHANICAL STRENGTH AND THROUGHPUT ON LOW-K DIELECTRIC FILMS

(71) Applicant: APPLIED MATERIALS, INC., Santa Clara, CA (US)

(72) Inventors: Kang Sub YIM, Palo Alto, CA (US); Mahendra CHHABRA, San Jose, CA (US); Alexandros T. DEMOS, Fremont, CA (US)

(21) Appl. No.: 14/766,964

(22) PCT Filed: Feb. 13, 2014
(86) PCT No.: PCT/US2014/016187

§ 371 Date: Aug. 10, 2015

Related U.S. Application Data
(60) Provisional application No. 61/779,910, filed on Mar. 13, 2013.

(51) Int. Cl. C23C 16/50; C23C 16/24; C23C 16/455

(52) U.S. Cl. CPC C23C 16/50; C23C 16/455; C23C 16/24

(57) ABSTRACT

A low k porous dielectric film with improved mechanical strength and methods for making the same are disclosed herein. A method of forming a dielectric layer can include positioning a substrate in a processing chamber, delivering a deposition gas to the processing chamber, depositing a dense organosilicon layer using the deposition gas on the surface of the substrate, the dense organosilicon layer comprising a porogenic carbon, forming a pore-forming plasma from a reactant gas, exposing the dense organosilicon layer to the pore-forming plasma to create a porous organosilicon layer, wherein the pore-forming plasma removes at least a portion of the porogenic carbon and exposing the porous organosilicon layer to ultraviolet (UV) radiation.

### BACKGROUND OF THE INVENTION

1. Field of the Invention

Embodiments disclosed herein generally relate to films having a low dielectric constant for use in the fabrication of electronic and semiconductor devices.

2. Description of the Related Art

As the semiconductor industry introduces new generations of integrated circuits (IC's) having higher performance and greater functionality, the density of the elements that form those IC's is increased, while the dimensions, size and spacing between the individual components or elements are reduced. While in the past such reductions were limited only by the ability to define the structures photolithographically, device geometries having dimensions measured in um or nm have created new limiting factors, such as the conductivity of the metallic elements or the dielectric constant of the insulating material(s) used between the elements.

In the field of advanced semiconductor fabrication, dielectrics with low k values are required for future generations of integrated circuits having design rules of less than or equal to 90 nanometers (nm) so as to reduce overall capacitance crosstalk. The term “low k dielectric” generally refers to materials having a dielectric constant that is generally less than about 3.9. More typically, for the advanced design rules, the dielectric constants of the low k dielectric materials are selected to be less than 3.0, and oftentimes less than 2.5. The dielectric films are generally deposited or formed using a spin-on process or by using a chemical vapor deposition (CVD) process.

To achieve the low K values which can be required by modern semiconductor devices, porous layers have been used to incorporate air (which has a K value of 1). Several methods have been pursued to induce porosity into low dielectric materials, such as organic, low-k polymers or organic polysilica, low-k polymers. One approach is to fabricate a hybrid organic-inorganic film using a mixture of silicon and organic precursors, with the film being subsequently cured using heat, electron beam (e-beam) or ultraviolet radiation (UV) to degrade the organic molecules. By degrading the organic molecules, pores are created but the mechanical strength of the layer is diminished

Therefore, there is a need for ultra low k dielectric films useful for the fabrication of IC devices which maintain mechanical strength.

### SUMMARY OF THE INVENTION

Embodiments disclosed herein generally relate to a method and apparatus for forming a low k porous dielectric film with improved mechanical strength. By decoupling the generation of pores from the crosslinking of the layer, we are able to generate a dielectric layer with both a low k value and increased mechanical strength.

In one embodiment, a method of forming a dielectric layer can include positioning a substrate in a processing chamber, delivering a deposition gas to the processing chamber, depositing a dense organosilicon layer using the deposition gas on the surface of the substrate, the dense organosilicon layer comprising a porogenic carbon, forming a pore-forming plasma from a reactant gas, exposing the dense organosilicon layer to the pore-forming plasma to create a porous organosilicon layer, wherein the pore-forming plasma removes at least a portion of the porogenic carbon and exposing the porous organosilicon layer to ultraviolet (UV) radiation.

In another embodiment, a method of forming a dielectric layer can include delivering a reactant gas to a substrate positioned in a processing chamber, the substrate comprising an organosilicon layer have porogenic compounds disposed therein; forming a pore-forming plasma from the reactant gas; exposing the organosilicon layer to the pore-forming plasma to create a porous organosilicon layer; and exposing the porous organosilicon layer to ultraviolet (UV) radiation.

In another embodiment, a method of forming a dielectric layer can include delivering a deposition gas to a substrate positioned in a processing chamber, the deposition gas comprising diethoxymethylsilane and bicycloheptadiene and a porogenic carbon gas; forming a plasma comprising the deposition gas to deposit a dense organosilicon layer on the surface of the substrate, the dense organosilicon layer comprising porogenic carbon compounds; activating the porogenic carbon compounds to create a porous organosilicon layer; and crosslinking the porous organosilicon layer by delivering ultraviolet (UV) radiation to the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a processing chamber configured according to one or more embodiments;

FIGS. 2A-2C depict a porous organosilicon layer formed according to one or more embodiments; and

FIG. 3 is a flow diagram of a method for forming a porous organosilicon layer according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate to method for forming an ultra low dielectric film. More specifically, embodiments disclosed herein generally relate to methods of generating an ultra low k film while maintaining mechanical strength of the deposited layer. In the embodiments described herein, an organosilicon layer is deposited on a substrate. The layer is then treated with an oxidative or reductive gas to remove carbon from the layer. This step creates pores without crosslinking the layer. After the carbon has been removed, the organosilicon layer is crosslinked using UV to form Si—O—Si bonds, thus creating a low K layer which maintains much of the mechanical strength of the deposited layer. The invention disclosed herein is more clearly described with reference to the figures below.

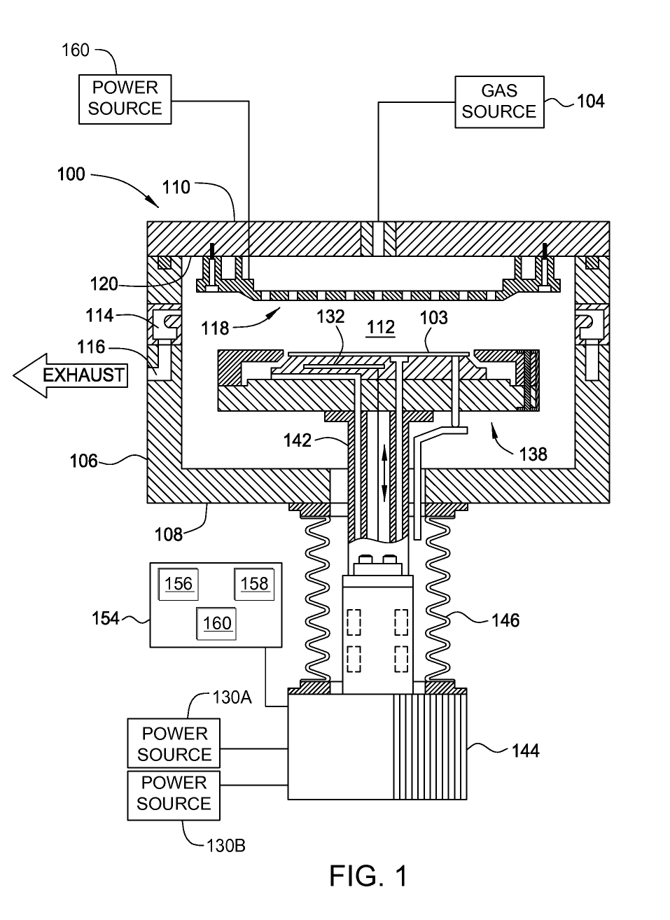

FIG. 1 is a schematic cross-sectional view of a CVD processing chamber 100 that may be used for depositing a carbon based layer according to the embodiments described herein. A processing chamber 100 is available from Applied Materials, Inc. located in Santa Clara, Calif., and a brief description thereof follows. Processing chambers that may be adapted to perform the carbon layer deposition methods described herein is the PRODUCER® chemical vapor deposition chamber, both available from Applied Materials, Inc. located in Santa Clara, Calif. It is to be understood that the chamber described below is an exemplary embodiment and other chambers, including chambers from the same or other manufacturers, may be used with or modified to match embodiments of this invention without diverging from the inventive characteristics described herein.

The processing chamber 100 may be part of a processing system (not shown) that includes multiple processing chambers connected to a central transfer chamber (not shown) and serviced by a robot (not shown). The processing chamber 100 includes walls 106, a bottom 108, and a lid 110 that define a process volume 112. The walls 106 and bottom 108 can be fabricated from a unitary block of aluminum. The processing chamber 100 may also include a pumping ring 114 that fluidly couples the process volume 112 to an exhaust port 116 as well as other pumping components (not shown).

A substrate support assembly 138, which may be heated, may be centrally disposed within the processing chamber 100. The substrate support assembly 138 supports a substrate 103 during a deposition process. The substrate support assembly 138 generally is fabricated from aluminum, ceramic or a combination of aluminum and ceramic, and includes at least one bias electrode 132.

A vacuum port may be used to apply a vacuum between the substrate 103 and the substrate support assembly 138 to secure the substrate 103 to the substrate support assembly 138 during the deposition process. The bias electrode 132, may be, for example, the electrode 132 disposed in the substrate support assembly 138, and coupled to a bias power source 130A and 130B, to bias the substrate support assembly 138 and substrate 103 positioned thereon to a predetermined bias power level while processing.

The bias power source 130A and 130B can be independently configured to deliver power to the substrate 103 and the substrate support assembly 138 at a variety of frequencies, such as a frequency between about 1 and about 60 MHz. Various permutations of the frequencies described here can be employed without diverging from the invention described herein.

Generally, the substrate support assembly 138 is coupled to a stem 142. The stem 142 provides a conduit for electrical leads, vacuum and gas supply lines between the substrate support assembly 138 and other components of the processing chamber 100. Additionally, the stem 142 couples the substrate support assembly 138 to a lift system 144 that moves the substrate support assembly 138 between an elevated position (as shown in FIG. 1) and a lowered position (not shown) to facilitate robotic transfer. Bellows 146 provide a vacuum seal between the process volume 112 and the atmosphere outside the chamber 100 while facilitating the movement of the substrate support assembly 138.

The showerhead 118 may generally be coupled to an interior side 120 of the lid 110. Gases (i.e., process and other gases) that enter the processing chamber 100 pass through the showerhead 118 and into the processing chamber 100. The showerhead 118 may be configured to provide a uniform flow of gases to the processing chamber 100. Uniform gas flow is desirable to promote uniform layer formation on the substrate 103. A plasma power source 160 may be coupled to the showerhead 118 to energize the gases through the showerhead 118 towards substrate 103 disposed on the substrate support assembly 138. The plasma power source 160 may provide RF power. Further, the plasma power source 160 can be configured to deliver power to the showerhead 118 at a at a variety of frequencies, such as a frequency between about 100 MHz and about 200 MHz. In one embodiment, the plasma power source 160 is configured to deliver power to the showerhead 118 at a frequency of 162 MHz.

The function of the processing chamber 100 can be controlled by a computing device 154. The computing device 154 may be one of any form of general purpose computer that can be used in an industrial setting for controlling various chambers and sub-processors. The computing device 154 includes a computer processor 156. The computing device 154 includes memory 158. The memory 158 may include any suitable memory, such as random access memory, read only memory, flash memory, hard disk, or any other form of digital storage, local or remote. The computing device 154 may include various support circuits 160, which may be coupled to the computer processor 156 for supporting the computer processor 156 in a conventional manner. Software routines, as required, may be stored in the memory 156 or executed by a second computing device (not shown) that is remotely located.

The computing device 154 may further include one or more computer readable media (not shown). Computer readable media generally includes any device, located either locally or remotely, which is capable of storing information that is retrievable by a computing device. Examples of computer readable media 154 useable with embodiments of the present invention include solid state memory, floppy disks, internal or external hard drives, and optical memory (CDs, DVDs, BR-D, etc). In one embodiment, the memory 158 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

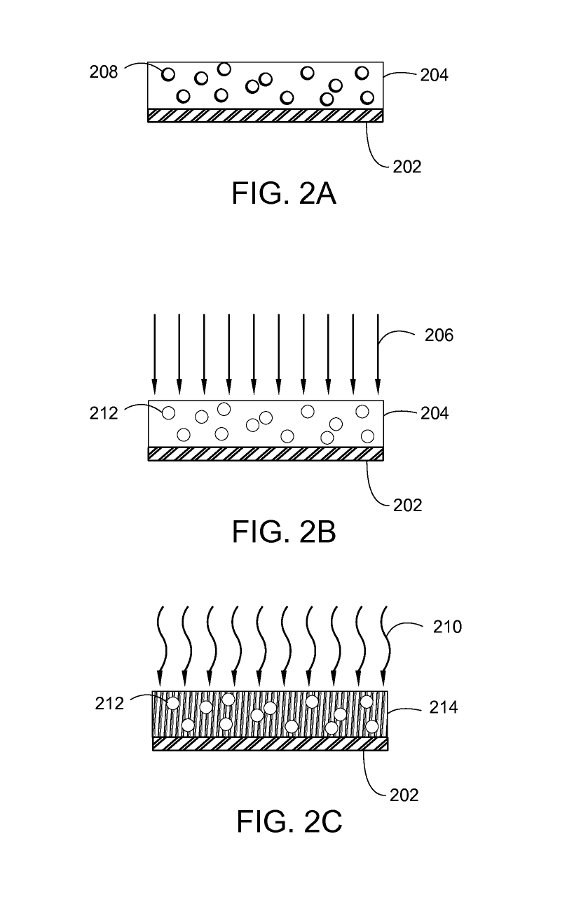

FIGS. 2A-2C depict a porous organosilicon layer formed according to one or more embodiments. The size, positioning and shape of components shown in FIGS. 2A-2C are not to scale and are shown for exemplary purposes only.

FIG. 2A depicts a substrate 202 with an organosilicon layer 204 formed thereon. The substrate 202 can be, among others, a thin sheet of metal, plastic, organic material, silicon, glass, quartz, or polymer materials. In one embodiment, the substrate 202 is a glass substrate upon which a silicon-containing layer will be deposited. In other embodiments, the substrate 202 may be a doped or otherwise modified glass substrate.

The organosilicon layer 204 can comprise silicon, oxygen, carbon and hydrogen, and can have the general formula, SiₐO_{b}C_{c}H_{d}, (in which the atomic % of a+b+c+d=100%; a=10-35%, b=1-66%, c=1-35%, d=0-60%). In one embodiment, the organosilicon layer can further comprise fluorine. The organosilicon layer 204 is generally deposited by CVD, such as PE-CVD, however the deposition technique used to deposit the organosilicon layer 204 is not intended to be limiting. The ratio and structural arrangement of carbon, silicon, oxygen, fluorine, and hydrogen atoms in the final organosilicon layer 204 is dependent on the precursors chosen, the oxidant, and the CVD process conditions, such as RF power, gas flow, residence time, and temperature.

The organosilicon layer 204 can be deposited using a deposition gas comprising one or more precursors. The precursors can comprise silicon and carbon. Precursors can include one or more precursors selected from the group consisting of diethoxymethylsilane, dimethoxymethylsilane, di-isopropoxymethylsilane, di-t-butoxymethylsilane, methyltriethoxysilane, methyltrimethoxysilane, methyltri-isopropoxysilane, methyltri-t-butoxysilane, dimethyldimethoxysilane, dimethyldiethoxysilane, dimethyldi-isopropoxysilane, dimethyldi-t-butoxysilane, and tetraethoxysilane, trimethylsilane, tetramethylsilane, methyltriacetoxysilane, methyldiacetoxysilane, methylethoxydi-siloxane, tetramethylcyclotetrasiloxane, octamethylcyclo-tetrasiloxane, dimethyldiacetoxysilane, bis(trimethoxysilyl)methane, bis(dimethoxysily)-methane, tetraethoxysilane, triethoxysilane, and mixtures thereof.

A porogenic carbon 208 is incorporated into the organosilicon layer 204. In this depiction, the porogenic carbon 208 is shown as embedded randomly in the organosilicon layer 204, however this arrangement is not intended to be limiting. The porogenic carbon 208 shown here is for explanation purposes only and may be a discrete component of the organosilicon layer 204 or may be a portion of a molecule which comprises the organosilicon layer 204. Porogenic carbons can include a member selected from the group consisting of cyclooctene, cycloheptene, cyclooctane, cycloheptane, cyclohexene, cyclohexane, and bicycle chemicals and mixtures thereof.

FIG. 2B depicts a pore-forming plasma 206 being delivered to the organosilicon layer 204 formed over the substrate 202. The pore-forming plasma 206 can include an oxidizing gas or a reducing gas. The pore-forming plasma 206 reacts with the porogenic carbon 208 to abstract at least a portion of the porogenic carbon 208 from the organosilicon layer 204 leaving behind a plurality of pores 212.

FIG. 2C depicts a substrate 202 having an organosilicon layer 204 with the plurality of pores 212 formed therein. The plurality of pores 212 are not depicted to scale and are based on the size and positioning of the porogenic carbon 208 which is displaced by the pore-forming plasma 206. In this depiction, the organosilicon layer 204 is shown receiving UV radiation 210. The UV radiation 210 creates a crosslinked organosilicon layer 214 by silicon-oxygen crosslinking, which is believed to improve mechanical strength of the layer.

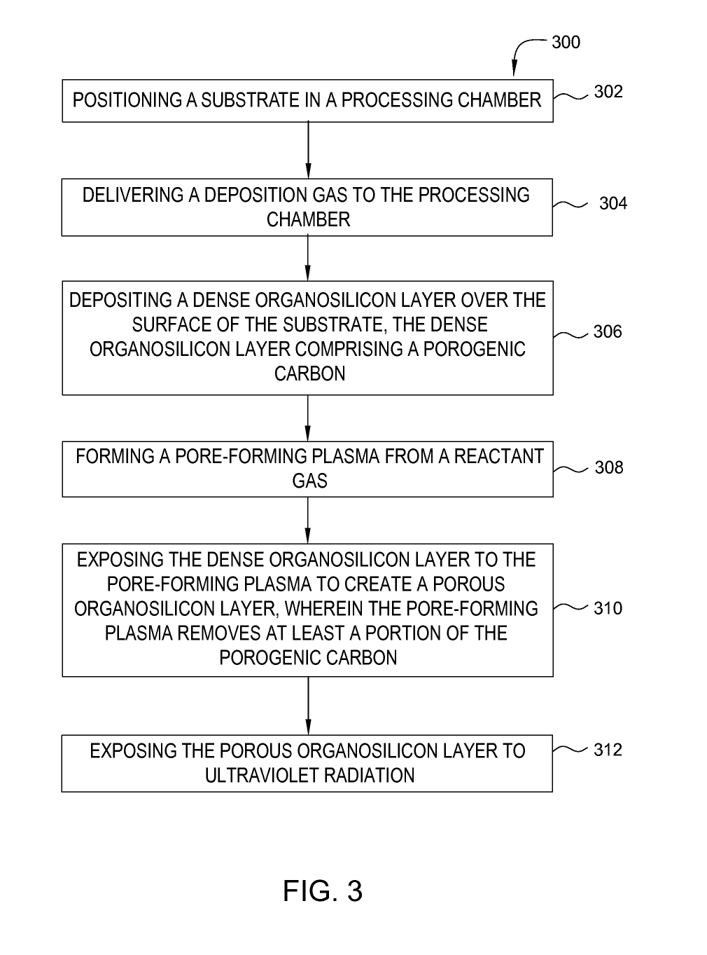

FIG. 3 is a flow diagram of a method 300 for depositing a dielectric layer according to one embodiment. The method 300 begins with positioning a substrate in a processing chamber, as in step 302. The substrate can be a substrate as described with reference to FIG. 2A. Suitable substrate materials can include but are not limited to glass, quartz, sapphire, germanium, plastic or composites thereof. Additionally, the substrate can be a relatively rigid substrate or a flexible substrate. Further, any suitable substrate size may be processed. Examples of suitable substrate sizes include substrate having a surface area of about 2000 centimeter square or more, such as about 4000 centimeter square or more, for example about 10000 centimeter square or more.

A deposition gas is then delivered to the processing chamber, as in step 304. One or more deposition gases may be used to deposit the dielectric layer. In one embodiment, the deposition gas includes a diethoxymethylsilane and bicycloheptadiene.

A dense organosilicon layer is deposited over the surface of the substrate, as in step 306. The dielectric layer can be deposited using the deposition gas by known techniques, such as CVD, PECVD, MW-PECVD, hotwire CVD or others. The dense organosilicon layer can comprise a porogenic carbon. Porogenic carbon is carbon which can be removed from the layer to form pores in the organosilicon layer. The layer can be deposited to a specific thickness such as between 50 Å and 500 Å. As described above, the organosilicon layer can be composed of silicon, carbon, oxygen and hydrogen in various proportions.

A pore-forming plasma is then formed from a reactant gas, as in step 308. The reactant gas can be either an oxidative gas or a reductive gas. In one embodiment, the reactant gas is an oxidative gas selected from the group ozone (O₃), H₂O, oxygen (O₂) or combinations thereof. In another embodiment, the reactant gas is a reductive gas comprising hydrogen (H₂), ammonia (NH₃), methane (CH₄) or other carbon-containing gases, or combinations thereof. The pore forming-plasma can be formed using one or more power sources known in the art, such as RF power or microwave power. Further, the pore forming plasma may be formed in the chamber or remotely.

The dense organosilicon layer is then exposed to the pore-forming plasma to create a porous organosilicon layer, as in step 310. The pore-forming plasma can remove at least a portion of the porogenic carbon. In one example, the pore-forming plasma reacts with and removes all available porogenic carbon.

The porous organosilicon layer is then exposed to UV radiation, as in step 312. After the porogenic carbon is at least partially removed from the organosilicon layer, the layer is then cured using UV radiation. The UV radiation is believed to create crosslinking between the oxygen and silicon, such as Si—O—Si bonding. The silicon-oxygen crosslinking is believed to enhance the mechanical strength of the layer.

Without intending to be bound by theory, generation of porosity when done simultaneously with crosslinking mechanically weakens the deposited layer. Porosity can be used to reduce the k value of a deposited layer. UV has been used to remove the porogenic carbon from the organosilicon layer while simultaneously crosslinking the layer to create this porosity. However, simultaneous pore generation and crosslinking is believed to result in mechanical weakening. By generating the porosity prior to crosslinking the layer, the organosilicon layer loses the porogenic carbon to the pore-forming plasma while it is more flexible. Thus, any damage created in the layer is believed to be minimized. The organosilicon layer can then be crosslinked without significant damage.

In one exemplary embodiment, an organosilicon layer was deposited on a substrate by PECVD. The organosilicon layer was treated by UV curing alone for 3 minutes. In this example, the refractive index was 1.4011. Shrinkage of the layer was 20.3%. The average k value of the layer was 2.60. The modulus of elasticity was 7.2 GPa. The ratio of SiCH3/SiO bonds was 3.60. The ratio of CH/SiO bonds was 1.46.

In another exemplary embodiment, an organosilicon layer was deposited on a substrate by PECVD. The organosilicon layer was treated with an ozone plasma for 15 seconds prior to UV curing for 1 minute. In this example, the refractive index was 1.3856. Shrinkage of the layer was 20.9%. The average k value of the layer was 2.60. The modulus of elasticity was 6.7 GPa. The ratio of SiCH3/SiO bonds was 3.75. The ratio of CH/SiO bonds was 1.50.

In another exemplary embodiment, an organosilicon layer was deposited on a substrate by PECVD. The organosilicon layer was treated with an ozone plasma for 15 seconds prior to UV curing for 2 minutes. In this example, the refractive index was 1.3907. Shrinkage of the layer was 23.0%. The average k value of the layer was 2.61. The modulus of elasticity was 7.4 GPa. The ratio of SiCH3/SiO bonds was 3.61. The ratio of CH/SiO bonds was 1.33.

In another exemplary embodiment, an organosilicon layer was deposited on a substrate by PECVD. The organosilicon layer was treated with an ozone plasma for 15 seconds prior to UV curing for 3 minute. In this example, the refractive index was 1.3961. Shrinkage of the layer was 24.1%. The average k value of the layer was 2.62. The modulus of elasticity was 8.0 GPa. The ratio of SiCH3/SiO bonds was 3.45. The ratio of CH/SiO bonds was 1.20.

The embodiments of the invention described herein generally relate to the formation of a porous mechanically strong dielectric layer. Current low k dielectric layers incorporate pores while simultaneously crosslinking the layer. Crosslinking while creating pores is believed to decrease the mechanical strength of the final layer. By decoupling the formation of pores from the crosslinking of the layer, we are capable of forming a low k dielectric layer with enhanced mechanical strength.

While the foregoing is directed to embodiments of the present invention, other and further embodiments of the invention may be devised without departing from the basic scope thereof, and the scope thereof is determined by the claims that follow.

1. A method of forming a dielectric layer comprising:
positioning a substrate in a processing chamber;
delivering a deposition gas to the processing chamber;
depositing a dense organosilicon layer using the deposition gas on the surface of the substrate, the dense organosilicon layer comprising a porogenic carbon;
forming a pore-forming plasma from a reactant gas;
exposing the dense organosilicon layer to the pore-forming plasma to create a porous organosilicon layer, wherein the pore-forming plasma removes at least a portion of the porogenic carbon; and
exposing the porous organosilicon layer to ultraviolet (UV) radiation.

2. The method of claim 1, wherein the reactant gas comprises an oxidative gas.

3. The method of claim 1, wherein the reactant gas comprises a reductive gas.

4. The method of claim 1, wherein the dense organosilicon layer comprises silicon, oxygen and carbon.

5. The method of claim 1, wherein the deposition gas comprises diethoxymethylsilane.

6. The method of claim 1, wherein the dense organosilicon layer is deposited using PECVD.

7. A method of forming a dielectric layer comprising:
delivering a reactant gas to a substrate positioned in a processing chamber, the substrate comprising an organosilicon layer have porogenic compounds disposed therein;
forming a pore-forming plasma from the reactant gas;
exposing the organosilicon layer to the pore-forming plasma to create a porous organosilicon layer; and
exposing the porous organosilicon layer to ultraviolet (UV) radiation.

8. The method of claim 7, wherein the reactant gas comprises an oxidative gas selected from the group comprising O₃, H₂O, O₂ or combinations thereof.

9. The method of claim 7, wherein the reactant gas comprises a reductive gas selected from the group consisting of H₂, NH₃, CH₄, a carbon-containing gas or combinations thereof.

10. The method of claim 7, wherein the dense organosilicon layer comprises silicon, oxygen and carbon.

11. The method of claim 7, wherein the porogenic compounds comprise cyclooctene, cycloheptene, cyclooctane, cycloheptane, cyclohexene, cyclohexane, and bicyclic chemicals and mixtures thereof.

12. The method of claim 7, wherein the organosilicon layer is between about 50 Å and about 500 Å thick.

13. A method of forming a dielectric layer, comprising:
delivering a deposition gas to a substrate positioned in a processing chamber, the deposition gas comprising diethoxymethylsilane and bicycloheptadiene and a porogenic carbon gas;
forming a plasma comprising the deposition gas to deposit a dense organosilicon layer on the surface of the substrate, the dense organosilicon layer comprising porogenic carbon compounds;
activating the porogenic carbon compounds to create a porous organosilicon layer; and
crosslinking the porous organosilicon layer by delivering ultraviolet (UV) radiation to the substrate.

14. The method of claim 13, wherein the porogenic carbon gas comprises cyclooctene, cycloheptene, cyclooctane, cycloheptane, cyclohexene, cyclohexane, and bicyclic chemicals and mixtures thereof.

15. The method of claim 13, wherein activating the porogenic carbon compounds comprises forming a pore-forming plasma from a reactant gas, the reactant gas comprising ozone, and exposing the dense organosilicon layer to the pore-forming plasma.

16. The method of claim 2, wherein the oxidative gas is selected from the group comprising O₃, H₂O, O₂ or combinations thereof.

17. The method of claim 3, wherein the reductive gas is selected from the group consisting of H₂, NH₃, CH₄, a carbon-containing gas or combinations thereof.

18. The method of claim 7, wherein the reactant gas comprises an oxidative gas.

19. The method of claim 7, wherein the reactant gas comprises a reductive gas.

20. The method of claim 17, wherein the UV radiation is delivered to the substrate for at least 1 minute.
